(19) United States
(12) Patent Application Publication
(10) Pub. No.: US 2019/0034270 A1
(43) Pub. Date: Jan. 31, 2019

(54) MEMORY SYSTEM HAVING AN ERROR CORRECTION FUNCTION AND OPERATING METHOD OF MEMORY MODULE AND MEMORY CONTROLLER

(71) Applicant: Samsung Electronics Co., Ltd., Suwon-si (KR)

(72) Inventors: Hui-chung BYUN, Hwaseong-si (KR); Seung-hun LEE, Hwaseong-si (KR); Sun-woo LEE, Incheon (KR)

(73) Assignee: Samsung Electronics Co., Ltd., Suwon-si, (KR)

(21) Appl. No.: 15/889,741

(22) Filed: Feb. 6, 2018

(30) Foreign Application Priority Data
Jul. 27, 2017 (KR) 10-2017-0095715

(51) Int. Cl. G06F 11/10; G11C 29/52

(52) U.S. Cl. CPC G06F 11/1068; G06F 11/1004; G11C 29/52

(57) ABSTRACT

A memory module including a plurality of memory chips each including DQ contact points which are grouped into at least one DQ group corresponding to a correction data width, a serial presence detect (SPD) chip configured to store DQ grouping information about the plurality of memory chips, and additional DQS contact points connected to the at least one DQ group, the additional DQS contact points configured to transmit signals to perform a data correction algorithm based on the correction data width in an error correction mode may be provided.

### CROSS-REFERENCE TO RELATED APPLICATION

This application claims priority under 35 U.S.C. § 119 to Korean Patent Application No. 10-2017-0095715, filed on Jul. 27, 2017, in the Korean Intellectual Property Office, the disclosure of which is incorporated herein in its entirety by reference.

### BACKGROUND

The inventive concepts relate to memory systems, and more particularly, to apparatuses and/or methods of correcting data of a memory module.

Along with technology developments, the capacity and speed of semiconductor memory devices are increasing. As an example of semiconductor memory devices, a volatile-memory device is a memory device that determines data by charges stored in a capacitor and loses data stored therein when a power supply thereto is interrupted.

As operation speed of a semiconductor memory device increases, an error may more likely occur in data. In order to mitigate or prevent performance degradation due to increase of error occurrence, various measures for correcting errors have been proposed.

### SUMMARY

The inventive concepts provide apparatuses and/or methods of DQ grouping DQ contact points of memory chips and implementing a data correction algorithm in a memory module and/or in a memory system.

According to an example embodiment, a memory module includes a plurality of memory chips each including DQ contact points which are grouped into at least one DQ group corresponding to a correction data width, a serial presence detect (SPD) chip configured to store DQ grouping information about the plurality of memory chips, and additional DQS contact points connected to the at least one DQ group, the additional DQS contact points configured to transmit signals to perform a data correction algorithm based on the correction data width in an error correction mode.

According to an example embodiment, a method of correcting an error of a memory module includes grouping DQ contact points of memory chips of the memory module into DQ groups corresponding to a correction data width, and performing data correction with respect to the memory module by the correction data width.

According to an example embodiment, A memory system includes a plurality of memory chips, and a memory controller configured to store DQ group management information about the plurality of memory chips. The memory controller may include an error correction code (ECC) engine connected to DQ contact points of each of the plurality of memory chips, the ECC engine configured to perform a data correction algorithm with respect to data transmitted to the DQ contact points, and a DQ group manager configured to group the DQ contact points into DQ groups corresponding to a correction data width and store the DQ group management information for managing the DQ groups.

### BRIEF DESCRIPTION OF THE DRAWINGS

Example embodiments of the inventive concepts will be more clearly understood from the following detailed description taken in conjunction with the accompanying drawings in which:

FIG. 1 is a diagram showing a memory system according to an example embodiment of the inventive concepts;

FIG. 2 is a diagram showing a burst operation of a memory module according to an example embodiment of the inventive concepts;

FIG. 3 is a diagram showing a data structure in which an error correction algorithm is performed according to an example embodiment of the inventive concepts;

FIG. 4 is a flowchart of a method of performing an error correction algorithm according to an example embodiment of the inventive concepts;

FIGS. 5A through 5C are diagrams showing a DQ-grouped DRAM chip according to an example embodiment of the inventive concepts;

FIG. 6 is a diagram showing a memory module according to an example embodiment of the inventive concepts;

FIG. 7 is a diagram showing a DQ group manager according to an example embodiment of the inventive concepts;

FIG. 8 is a diagram showing a data structure in which an error correction algorithm is performed on the memory module of FIG. 6, according to an example embodiment of the inventive concepts;

FIG. 9 is a diagram showing a memory module according to an example embodiment of the inventive concepts;

FIG. 10 is a diagram showing a data structure in which an error correction algorithm is performed on the memory module of FIG. 9 according to an example embodiment of the inventive concepts;

FIG. 11 is a diagram showing the memory module according to an example embodiment of the inventive concepts;

FIG. 12 is a diagram showing a data structure in which an error correction algorithm is performed on the memory module of FIG. 11 according to an example embodiment of the inventive concepts;

FIG. 13 is a diagram showing a memory module according to an example embodiment of the inventive concepts;

FIG. 14 is a diagram showing a memory module according to an example embodiment of the inventive concepts;

FIG. 15 is a diagram showing a DQ group manager according to an example embodiment of the inventive concepts;

FIG. 16 is a diagram showing a memory module according to an example embodiment of the inventive concepts;

FIG. 17 is a diagram a memory system according to an example embodiment of the inventive concepts;

FIG. 18 is a flowchart showing that a memory controller performs an error correction function when memory chips of a memory module are DQ-grouped; and

FIG. 19 is a block diagram showing a data processing system according to an example embodiment of the inventive concepts.

### DETAILED DESCRIPTION

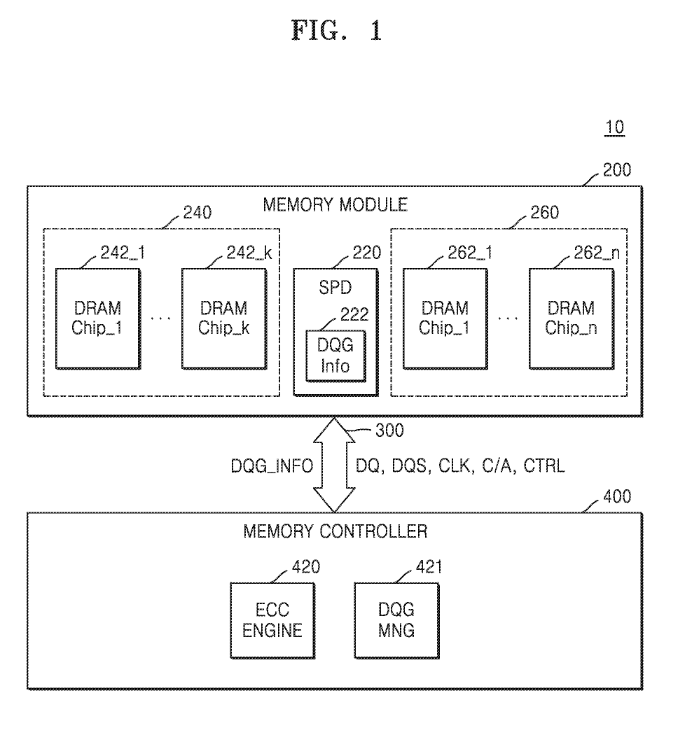

FIG. 1 is a diagram showing a memory system 10 according to an example embodiment of the inventive concepts.

The memory system 10 may include a memory module 200 and a memory controller 400. The memory module 200 and the memory controller 400 may exchange various signals, for example, DQ. DQS, and CLK through a bus 300. The memory system 10 may include only one memory module 200 or a plurality of memory modules. The memory system 10 may be included in various electronic devices that need memories, such as servers, desktop PCs, laptop PCs, smart phones, tablet PCs, printers, scanners, monitors, digital cameras, digital music players, digital media recorders, and portable game consoles. However, the inventive concepts are not limited thereto.

The memory module 200 may temporarily store data to be processed by a processor or data that has been processed by the processor. The memory module 200 may be used as an operation memory, a working memory, and/or a buffer memory in a computing system. The memory module 200 may include a plurality of memory ranks, for example, first and second memory ranks 240 and 260 and a serial presence detect (SPD) chip 220. The memory module 200 may include, but is not limited to, two memory ranks, as shown in FIG. 1. In some example embodiments, the memory module 200 may include a single memory rank or three or more memory ranks. The memory module 200 may be implemented as a single in-line memory module (SIMM), a dual in-line memory module (DIMM), a small-outline DIMM (SO-DIMM), an unbuffered DIMM (UDIMM), a fully-buffered DIMM (FBDIMM), a rank-buffered DIMM (RBDIMMs), a mini-DIMM, or a micro-DIMM. The memory module 200 may be implemented as a registered DIMM (RDIMM) or a load-reduced DIMM (LRDIMM) in a server.

The first and second memory ranks 240 and 260 may include a plurality of memory chips 242_1 through 242_k and plurality of memory chips 262_1 through 262_n, respectively (k and n are natural numbers). For convenience of explanation, descriptions of the first and second memory ranks 240 and 260 are replaced with description of the first memory rank 240. The first memory rank 240 may include k memory chips 242_1 through 242_k, where k is a natural number. Each of the memory chips 242_1 through 24_k may be a volatile memory (e.g., dynamic random access memory (DRAM), synchronous DRAM (SDRAM), double data rate SDRAM (DDR SDRAM), low power double data rate SDRAM (LPDDR SDRAM), graphics double data rate SDRAM (GDDR SDRAM), Rambus DRAM (RDRAM), or static RAM (SRAM)), or a non-volatile memory (e.g., phase-change RAM (PRAM), magneto-resistive RAM (MRAM), resistive RAM (ReRAM), ferroelectric RAM (FRAM), or a flash memory). Each of the memory chips 242_1 through 242_k may correspond to a DRAM chip complying with various standards, such as DDR, DDR2, DDR3, DDR4, and DDR5.

Descriptions below will be given under an assumption that each of the memory chips 242_1 through 242_k is a DRAM chip. However, the memory chips 242_1 through 242_k are not limited thereto and may be any of various other types of chips.

An SPD chip 220 may store information about the characteristics of the memory module 200. The SPD chip 220 may store information about the memory module 200, for example, a module type, an operating environment, a line arrangement, a module configuration, and/or a storage capacity of the memory module 200. The SPD chip 220 may include a programmable read-only memory (e.g., electrically erasable programmable read-only memory (EEPROM)). The SPD chip 220 may store DQ grouping information DQG_INFO about whether the memory chips 242_1 through 242_k and 262_1 through 262_n included in the memory module 200 are DQ grouped. In an error correction mode of the memory module 200, the SPD chip 220 may provide DQ group information DQG_INFO to the memory controller 400 such that the memory controller 400 may access the memory module 200 based on DQ grouping information. Detailed description of a DQ group will be given below

The bus 300 may include various buses, for example, a control bus, a command/address bus, and/or a data bus. The memory controller 400 may transmit and receive a command/address signal C/A, a clock signal CLK, a control signal CTRL, data DQ, and/or a data strobe signal DQS to and from the memory module 200 via the bus 300. The memory controller 400 may control reading of data DQ from the memory module 200 and writing of the data DQ to the memory module 200. The memory controller 400 may provide a command/address signal C/A and a control signal CTRL to the memory module 200, and control transmission and reception of data DQ to and from a memory chip (e.g., to and from the plurality of memory chips 242_1 through 242_k and 262_1 through 262_n) based on the control signal CTRL in a write mode or a read mode configured according to the command/address signal C/A. Furthermore, the memory module 200 may provide the DQ grouping information DQG_INFO to the memory controller 400 through the bus 300. The DQ grouping information DQG_INFO may include information about whether the memory chips 242_1 through 242_k and 262_1 through 262_n included in the memory module 200 are DQ grouped.

The memory controller 400 may provide an interface with respect to the memory module 200 to manage flow of data to and from the memory module 200. The memory controller 400 may be connected to an external host, for example, a processor, and may communicate with the external host via at least one of various interface protocols, for example, USB, MMC, PCIe, advanced technology attachment (ATA), serial-ATA, parallel-ATA, SCSI, ESDI, or integrated drive electronics (IDE). The memory controller 400 may be implemented as an independent chip or may be integrated with the memory module 200. The memory controller 400 may be implemented on a motherboard and may be implemented as an integrated memory controller (IMC) included in a microprocessor. Furthermore, the memory controller 400 may be located in an input/output hub, and the input/output hub including the memory controller 400 may be referred to as a memory controller hub (MCH).

The memory controller 400 may include an ECC engine 420 to perform error detection and error correction. The ECC engine 420 may use, for example, a parity check, a cyclic redundancy code (CRC) check, a checksum check, and/or a hamming code to detect and correct an error. The ECC engine 420 may use a correction technique, for example, ×4 single device data correction (SDDC), ×8 single-bit error correction and double-bit error detection (SECDED), or Lockstep ×8 SDDC.

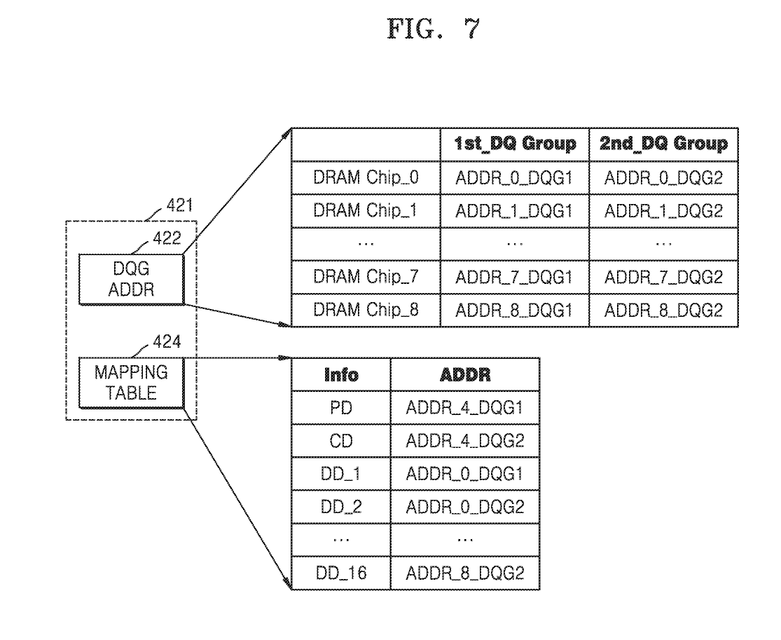

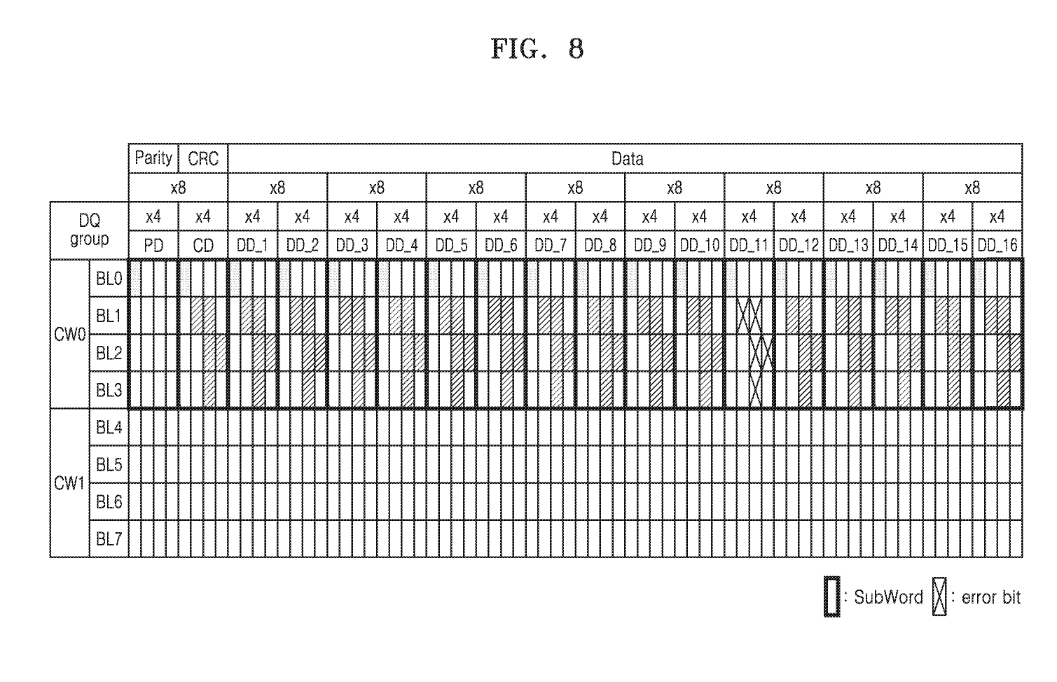

The memory controller 400 may include a DQ group manager 421 that stores DQ group management information DQG MNG for managing DQ groups included in the memory chips 242_1 through 242_k and 262_1 through 262_n. Referring to FIG. 7, the DQ group management information DQG MNG may include DQ group address information DQG ADDR, which include address information about the DQ groups.

In the error correction mode of the memory module 200, the ECC engine 420 may receive DQ group management information DQG MNG from the DQ group manager 421, recognize each of DQ group units by which the memory chips 242_1 through 242_k and 262_1 through 262_n are grouped based on the DQ group management information DQG MNG, and perform an error correction function.

The memory chips 242_1 through 242_k and 262_1 through 262_n in the memory module 200 may operate according to data bus width characteristics. The data bus width may be one of 4 bits, 8 bits, 16 bits, and 32 bits, but is not limited thereto. For example, a memory chip including DRAM with a data bus width of 4 bits may be referred to as an ×4 DRAM chip, and the ×4 DRAM chip may transmit and receive data to and from an external device through four DQ contact points. The DQ contact points may be pins. The term ‘pin’ may refer to a wide variety of electrical interconnections with respect to an integrated circuit or the like, and thus may include, for example, pads or other electrical contact points on an integrated circuit. The ×4 DRAM chip may transmit and receive 4-bit data simultaneously through 4 DQ contact points. Furthermore, for example, a memory chip including DRAM with a data bus width of 8 bits may be referred to as an ×8 DRAM chip, and the ×8 DRAM chip may transmit and receive data to and from an external device through eight DQ contact points. The ×8 DRAM chip may transmit and receive 8-bit data simultaneously through 8 DQ contact points.

The number of the memory chips 242_1 through 242_k included in one memory rank may be determined by a DDR bus width and a data bus width of each of the memory chips 242_1 through 242_k. For example, when the first memory rank 240 is an ×4 ECC DIMM and the DDR bus width is 72 bits, each data bus width is 4 bits, and thus 18 memory chips may be desired. In another example, when the first memory rank 240 is an ×8 ECC DIMM and the DDR bus width is 72 bits, each data bus width is 8 bits, and thus 9 memory chips may be desired. However, example embodiments according to the inventive concepts are not limited thereto. According to the inventive concepts, the memory chips 242_1 through 242_k may not have a same data bus width, and thus the number k of the memory chips may also vary.

When the ECC engine 420 in the memory controller 400 performs an error correction function with respect to the memory module 200 as one rank module in the error correction mode, data may be read by a specific data width unit to fill a cache line of the memory controller 400. At that time, the specific data width may be referred to as a correction data width. The ECC engine 420 may fill a cache line, perform an error correction algorithm with respect to each correction data width to detect an error, and correct the error. When an error is corrected, the memory controller 400 may perform an operation for rewriting corrected data to a corresponding memory chip. In order for an error correction algorithm to be performed with respect to each correction data width, each of the memory chips 242_1 through 242_k or 262_1 through 262_n may be desired to have a data bus width identical to a correction data width. Therefore, when the data bus width of the memory chips 242_1 through 242_k and 262_1 through 262_n is greater than the correction data width, it may be difficult to implement an error correction algorithm to be performed with respect to each correction data width in the memory module 200.

In order to implement an error correction algorithm to be performed with respect to each correction data width in the memory module 200, which includes the memory chips 242_1 through 242_k having a data bus width greater than the correction data width, the memory controller 400 may group the memory chips 242_1 through 242_k into DQ groups corresponding to the correction data width. For example, when the correction data width is 4 bits and the data bus width of the memory chips 242_1 through 242_k is 8 bits, eight DQ contact points DQ0 through DQ7 included in each of the memory chips 242_1 through 242_k may be grouped into a first DQ group (e.g., DQ0 through DQ3) and a second DQ group (e.g., DQ4 through DQ7). As the DQ contact points DQ0 through DQ7 are grouped, the memory controller 400 may recognize the memory chips 242_1 through 242k as two DQ group memory chips, and thus each of the two DQ group memory chips may be recognized as a memory chip having a data bus width of 4 bits. As described above, when the memory controller 400 recognizes memory chips of the memory module 200 as DQ group memory chips having a 4-bit data bus width equal to the correction data width, although each of the memory chips 242_1 through 242_k has a data bus width of 8 bits, the ECC engine 420 may implement an error correction algorithm configured to perform, for example, 4-bit based operations with regard to the memory module 200. In other words, when the data bus width of memory chips is N times (N is a natural number equal to or greater than 2) a correction data width, DQ contact points of the memory chips may be grouped into N DQ groups, and a memory controller may recognize the memory chips as N DQ group memory chips.

In the error correction mode, the memory controller 400 may receive a DQ grouping information DQG_INFO signal from the SPD chip 220 of the memory module 200 and determine whether the memory chips 242_1 through 242_k included in the memory module 200 are grouped into DQ groups. When the memory chips 242_1 through 242_k are grouped into a DQ group having the same data bus width as the correction data bus width, to recognize the DQ groups as one memory chip (DQ group memory chip) and implement an error correction algorithm, the memory controller 400 may include a DQ group manager 421 for storing DQ group management information DQG MNG. Referring to FIG. 7, the DQ group management information DQG MNG may include DQ group address information DQG ADDR. The DQ group address information DQG ADDR may include address information about the memory chips 242_1 through 242_k. Therefore, the memory controller 400 may recognize whether memory chips are grouped based on a received DQ grouping information DQG_INFO signal and perform an error correction algorithm for each DQ group based on DQ group management information DQG MNG.

The ECC engine 420 and the DQ group manager 421 described herein may not be provided as separate units or modules, but may be implemented using hardware components and a combination of software components and hardware component. For example, the hardware components may be a processing device. The processing device may be implemented using one or more hardware device(s) configured to carry out and/or execute program code by performing arithmetical, logical, and input/output operations. The processing device may include a processor, a controller and an arithmetic logic unit, a digital signal processor, a microcomputer, a field programmable array, a programmable logic unit, a microprocessor or any other device capable of responding to and executing instructions in a defined manner. The processing device may run an operating system (OS) and one or more software applications that run on the OS. The processing device also may access, store, manipulate, process, and create data in response to execution of the software. For simplicity, the description of a processing device is used as singular, however, one skilled in the art will appreciated that a processing device may include multiple processing elements and multiple types of processing elements. For example, a processing device may include multiple processors or a processor and a controller. In addition, different processing configurations are possible, such as parallel processors, multi-core processors, distributed processing, or the like.

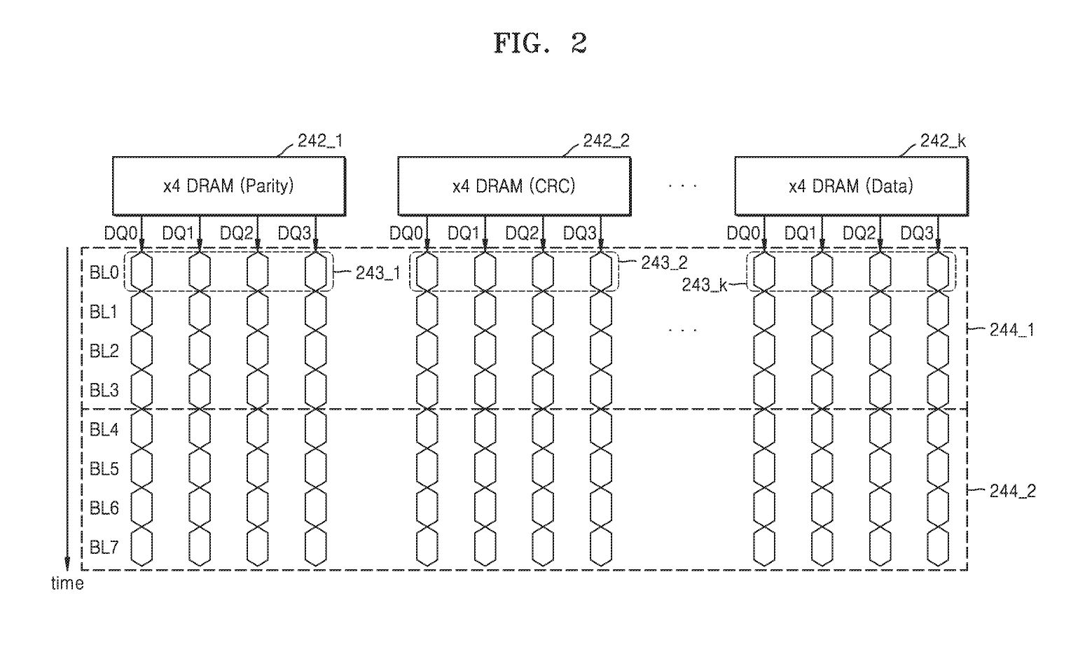

FIG. 2 is a diagram showing a burst operation of a memory module according to an example embodiment of the inventive concepts.

Referring to FIG. 2, a memory module may include one memory rank, and one memory rank may include a plurality of ×4 DRAM chips 242_1 through 242_k. The memory module may be an ×4 ECC DIMM including an error correction code (ECC). The memory module may include a DRAM chip 242_1 that stores parity data and may include a DRAM chip 242_2 that stores cyclical redundancy code (CRC) data. For example, when a memory module is an ×4 ECC DIMM having a total bus width of 72 bits, because the total number of memory chips of the memory module is 18, the memory module may include 16×4 DRAM chips other than the parity DRAM chip 242_1 and the CRC DRAM chip 242_1, but the inventive concepts are not limited thereto. The data bus width of each of ×4 DRAM chips 242_1 through 242_k is 4 bits. When each of the DRAM chips 242_1 through 242_k outputs data, 4-bit data may be output simultaneously through four DQ contact points DQ0 through DQ3. 4-bit data 243_1 through 243_k may be simultaneously output from the DRAM chips 242_1 through 242_k, respectively.

The plurality of DRAM chips 242_1 through 242_k may perform a burst operation. A burst operation may refer to an operation for reading or writing a large amount of data by sequentially decreasing or increasing an address from an initial address received from a memory controller. The basic unit for performing a burst operation may be referred to as a burst length (BL). Referring to FIG. 2, the BL may be 8. The DQ contact point DQ0 through DQ3 of each of the DRAM chips 242_1 through 242_k may input and output eight pieces of data BL0 through BL7 as a basic unit of a burst operation. For example, in the case of an ×4 ECC DIMM, data input and output per unit task during a burst operation may be 8 (BL)×4 (data bus width)×18 (number of chips)=576 bits. 576 bits may fill one cache line of a memory controller. A unit by which error correction is performed may be defined as one code word. For example, in the error correction mode of an ×4 ECC DIMM, each error correction may be performed for half cache line. Therefore, the basic unit of a burst operation for filling one cache line may include two code words. Referring to FIG. 2, the basic unit of a burst operation may include a first code word 244_1 and a second code word 244_2. In the case of an ×4 ECC DIMM, each of the first and second code words 244_1 and 244_2 may include 288 bits of data. An ECC engine of the memory controller may implement an error correction algorithm with respect to 288-bit data of each of the first and second code words 244_1 and 244_2.

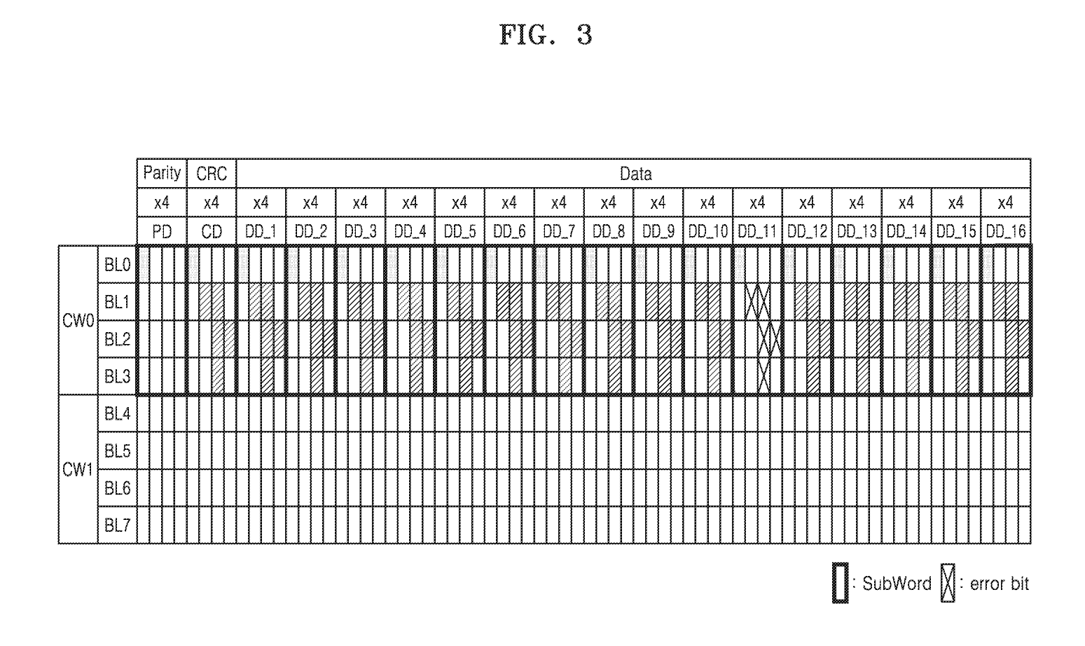

FIG. 3 is a diagram showing a data structure in which an error correction algorithm is performed according to an example embodiment of the inventive concepts. A memory module may include one memory rank and may be an ×4 ECC DIMM including 18×4 DRAM chips. One of the 18×4 DRAM chips may be a parity DRAM chip PD for storing parity data, and another one may be a CRC DRAM chip CD for storing CRC data. The memory module may include 16×4 DRAM chips DD_1 through DD_16 for storing data. FIG. 3 shows data output from the memory module configured as an ×4 ECC DIMM per unit burst operation. The BL may be 8. A total of 576 bits of data may fill one cache line of a memory controller and constitute two code words CW0 and CW1. The memory controller may perform an error correction algorithm based on the code words.

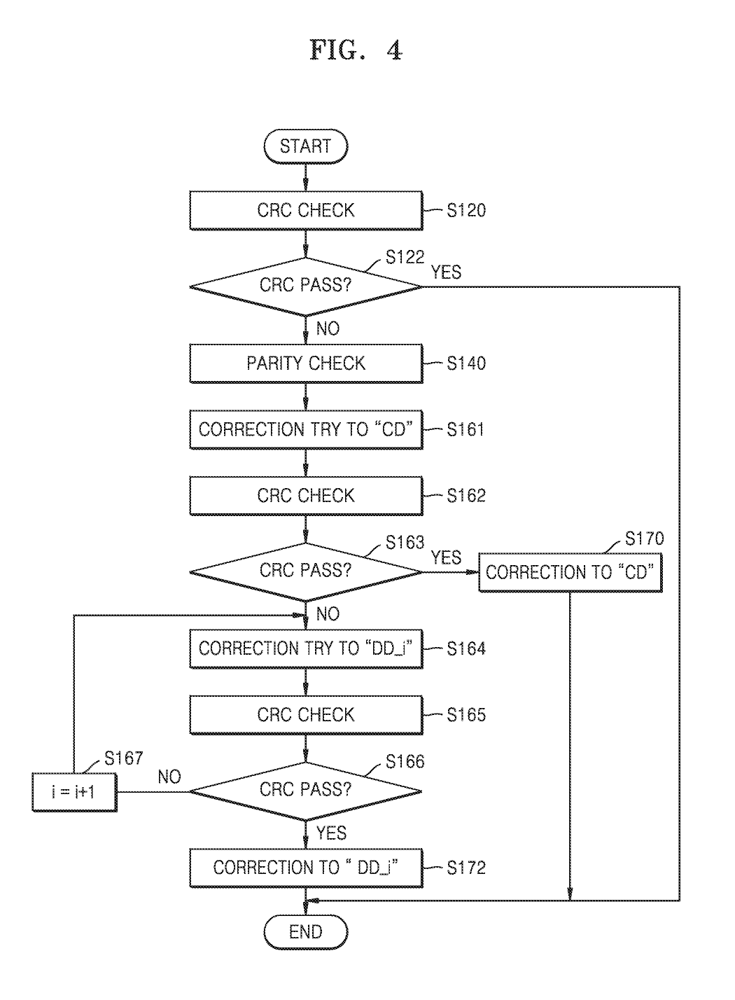

FIG. 4 is a flowchart of a method of performing an error correction algorithm according to an example embodiment of the inventive concepts.

FIG. 4 may be described with reference to FIG. 3. A method of detecting and correcting an error bit will be described under an assumption that an error has occurred in an eleventh data DRAM chip DD_11 belonging to the first code word CW0 of FIG. 3. CRC check may be initially performed with respect to a code word unit (operation S120). When CRC check is performed with respect to the entire first code word CW0, pass or failure of the CRC check may be determined (operation S122). When the CRC check passes, an error correction algorithm may be terminated because there is no error in the first code word CW0. When the CRC check fails (operation S122), there is an error in the first code word CW0, and thus a next step may be performed to locate an error bit in which the error exists.

Therefore, when The CRC check fails, a parity check may be performed (operation S140). Referring to FIG. 3, for convenience of description, 16-bit data grouped by the data bus width of 4 bits in the first code word CW0 according to a data bus width may be referred to as a sub-word. The first code word CW0 may include a total of 18 sub-words. One parity check may be performed on data corresponding to a same location from among data included in one of the 18 sub-words, and a total of 16 parity checks may be performed. Although the parity check may be an even parity check, the inventive concepts are not limited thereto, and the parity check may also be an odd parity check. By performing parity check, the location of an error bit in sub-words may be determined. Referring to FIG. 3, there are errors at bits (hatched portions) existing at locations of (2, 2), (2, 3), (3, 3), (3, 4), and (4, 3) within one sub-word. After locating the error bit in the sub-word, a next operation may be performed to find out a device with the error bit.

First, correction may be attempted with respect to a sub-word corresponding to a CRC DRAM chip CD (operation S161). Next, a CRC check may be performed (operation S162). Pass or failure of the CRC check may be determined (operation S163). When The CRC check passes, it may be determined that the CRC DRAM chip CD is a device with an error and error correction may be performed on the CRC DRAM chip CD (operation S170). When The CRC check fails, it may be determined that the CRC DRAM chip CD is not a device with an error, and the process may proceed to a next operation. Next, correction may be attempted with respect to a sub-word corresponding to a DD_1 DRAM chip (operation S164). Next, CRC check may be performed (operation S165). Then, pass and failure of the CRC check may be determined (operation S166). When The CRC check passes, it may be determined that the DD_1 DRAM chip is a device with an error and error correction may be performed on the DD_1 DRAM chip (operation S172). When The CRC check fails, it may be determined that the DD_1 DRAM chip is not a device with an error, and the process may proceed to a next operation. Next, since it is desired to attempt correction with respect to a sub-word corresponding to a DD_2 DRAM chip, 1 may be added to a sequence factor i (operation S167). Next, correction may be attempted with respect to a sub-word corresponding to the DD_2 DRAM chip (operation S164), and operations thereafter may be repeated in the same manner until the CRC check passes.

As a result, it may be determined that there is an error in a device that passed CRC, and a final error correction may be performed with respect to the device (operation S172). Accordingly, an error correction algorithm that detects and corrects errors existing in a device may be completed. Of course, other types of error correction algorithms may also be performed in the error correction mode. Thus, error correction algorithms are not limited to the algorithm described in FIG. 4.

Because correction may be attempted with respect to each sub-word while an error correction algorithm is being performed as described above, it may be desired for a correction data width for performing the error correction algorithm to be identical to a data bus width of a memory chip in which the error correction algorithm is implemented. As data bus widths of memory chips are becoming wider, it may be desired to implement an error correction algorithm enabling error correction for a memory chip having a data bus width greater than a correction data width.

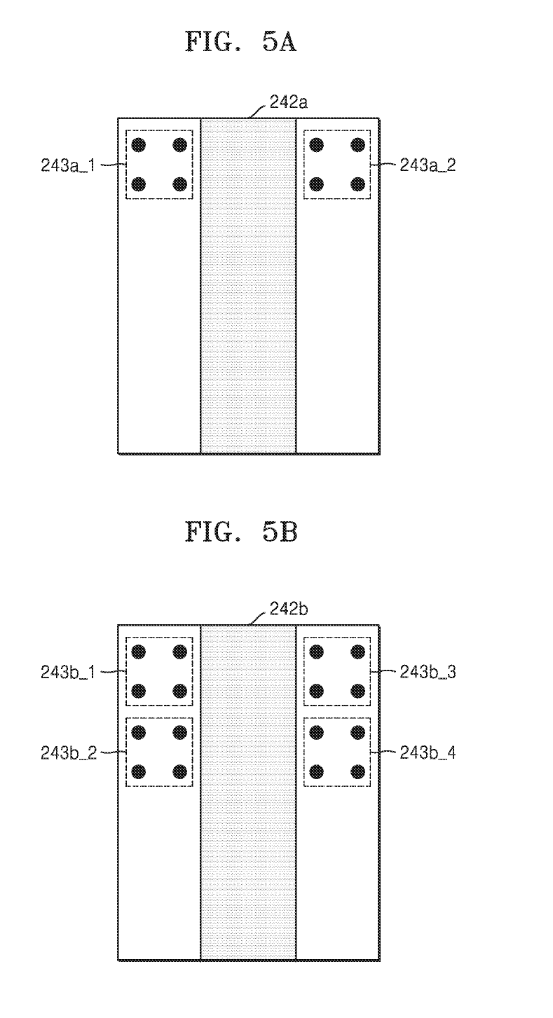

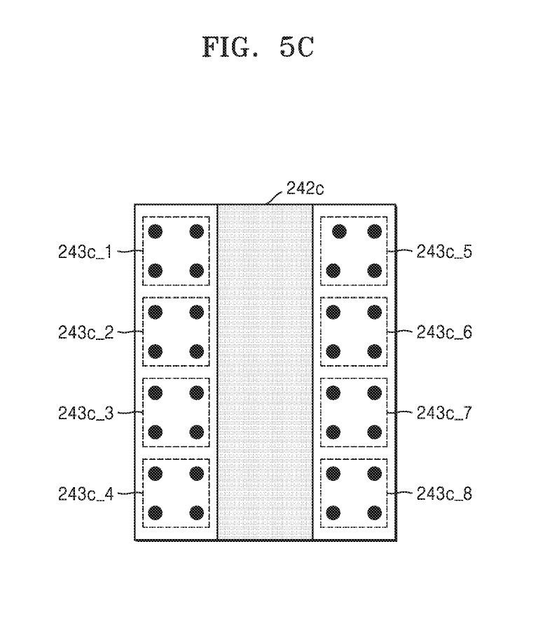

FIGS. 5A through 5C are diagrams showing a DQ-grouped DRAM chip according to an example embodiment of the inventive concepts.

Referring to FIG. 5A, the DRAM chip 242a may have eight DQ contact points. In other words, the data bus width of the DRAM chip 242a may be 8 bits and the DRAM chip 242a may be referred to as an ×8 DRAM chip. Pins may be DQ contact points DQ0 through DQ7 of the DRAM chip 242a. The term “pin(s)” refers broadly to an electrical interconnection(s) to an integrated circuit, and may include, for example, a pad(s) or other electrical contact point(s) on an integrated circuit. The DQ contact points DQ0-DQ7 of the DRAM chip 242a may be grouped into DQ groups 243a_1 and 243a_2 by 4 bits in order to implement a 4 bit based error correction algorithm with regard to the DRAM chip 242a in the error correction mode. For example, DQ contact points DQ0 through DQ3 may be grouped into a first DQ group 243a_1, and DQ contact points DQ4 through DQ7 may be grouped into a second DQ group 243a_2. Therefore, in the error correction mode, a memory controller may recognize the DRAM chip 242a as a first ×4 DQ memory chip, which includes the first DQ group 243a_1 as a DQ contact point, and a second ×4 DQ memory chip, which includes the second DQ group 243a_2 as a DQ contact point. Thus, even though the data bus width of the DRAM chip 242a is 8 bits, an error correction algorithm performed by, for example, 4 bits may be implemented with regard to the DRAM chip 242a.

Referring to FIG. 5B, a DRAM chip 242b may have 16 DQ contact points. In other words, the data bus width of the DRAM chip 242b may be 16 bits and the DRAM chip 242b may be referred to as an ×16 DRAM chip. Respective dots may be DQ contact points DQ0 through DQ15 of the DRAM chip 242b. The DQ contact point DQ0 through DQ15 of the DRAM chip 242b may be grouped into DQ groups 243b_1, 243b_2, 243b_3, and 243b_4 by 4 bits in order to implement a 4 bit based error correction algorithm with regard to the DRAM chip 242b in the error correction mode. For example, DQ contact points DQ0 through DQ3 may be grouped into a first DQ group 243b_1, DQ contact points DQ4 through DQ7 may be grouped into a second DQ group 243b_2, DQ contact points DQ8 through DQ11 may be grouped into a third DQ group 243b_3, and DQ contact points DQ12 through DQ15 may be grouped into a fourth DQ group 243b_4. Therefore, in the error correction mode, a memory controller may recognize the DRAM chip 242b as a first ×4 DQ memory chip having the first DQ group 243b_1 as a DQ contact point, a second ×4 DQ memory chip having the second DQ group 243b_2 as a DQ contact point, a third ×4 DQ memory chip having the third DQ group 243b_3 as a DQ contact point, and a fourth ×4 DQ memory chip having the fourth DQ group 243b_4 as a DQ contact point. Therefore, even though the data bus width of the DRAM chip 242b is 16 bits, an error correction algorithm performed by, for example, 4 bits may be implemented with regard to the DRAM chip 242b.

Referring to FIG. 5C, a DRAM chip 242c may have 32 DQ contact points. In other words, the data bus width of the DRAM chip 242c may be 32 bits and the DRAM chip 242c may be referred to as an ×32 DRAM chip. Respective dots may be DQ contact points DQ0 through DQ31 of the DRAM chip 242c. The DQ contact points DQ0 through DQ31 of the DRAM chip 242c may be grouped into the DQ group 243c_1, 243c_2, 243c_3, 243c_4, 243c_5, 243c_6, 243c_7, and 243c_8 by 4 bits in order to implement a 4 bit based error correction algorithm with regard to the DRAM chip 242c in the error correction mode. For example, DQ contact points DQ0 through DQ3 may be grouped into a first DQ group 243c_1, DQ contact points DQ4 through DQ7 may be grouped into a second DQ group 243c_2, DQ contact points DQ8 through DQ11 may be grouped into a third DQ group 243c_3, DQ contact points DQ12 through DQ15 may be grouped into a fourth DQ group 243c_4, DQ contact points DQ16 through DQ19 may be grouped into a fifth DQ group 243c_5, DQ contact points DQ20 through DQ23 may be grouped into a sixth DQ group 243c_6, DQ contact points DQ24 through DQ27 may be grouped into a seventh DQ group 243c_7, and DQ contact points DQ28 through DQ31 may be grouped into an eighth DQ group. Therefore, in the error correction mode, a memory controller may recognize the DRAM chip 242c as an ×4 DQ memory chip having the first DQ group 243c_1 as a DQ contact point, an ×4 DQ memory chip having the second DQ group 243c_2 as a DQ contact point, an ×4 DQ memory chip having the third DQ group 243c_3 as a DQ contact point, an ×4 DQ memory chip having the fourth DQ group 243c_4 as a DQ contact point, an ×4 DQ memory chip having the fifth DQ group 243c_5 as a DQ contact point, an ×4 DQ memory chip having the sixth DQ group 243c_6 as a DQ contact point, an ×4 DQ memory chip having the seventh DQ group 243c_7 as a DQ contact point, and an ×4 DQ memory chip having the eighth DQ group 243c_8 as a DQ contact point.

Therefore, even though the data bus width of the DRAM chip 242c is 32 bits, an error correction algorithm performed by, for example, 4 bits may be implemented with regard to the DRAM chip 243b.

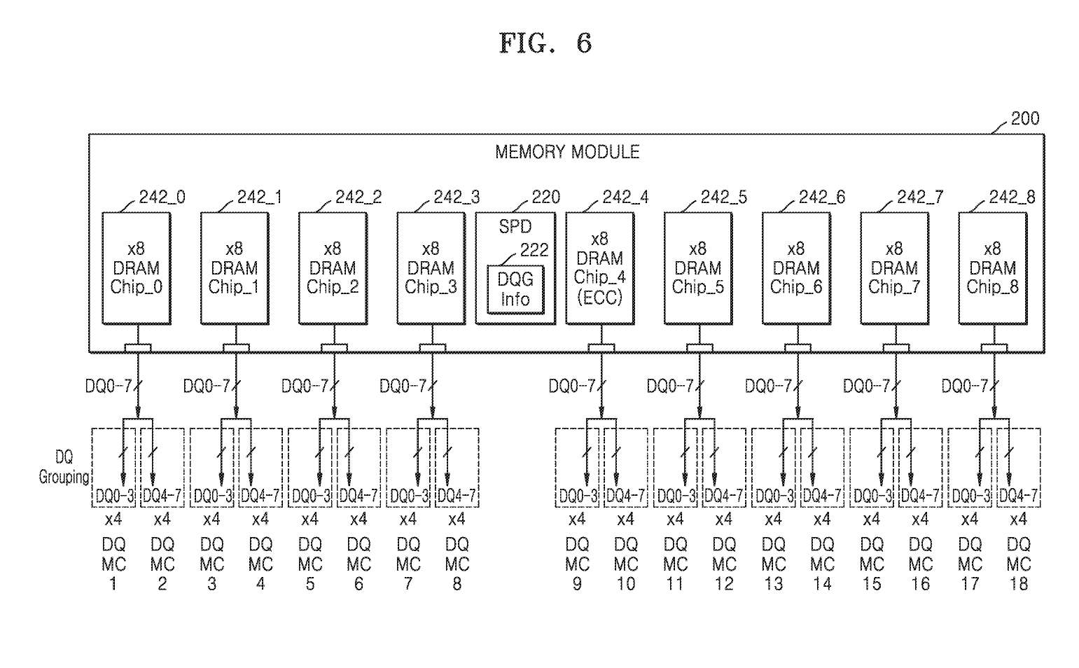

FIG. 6 is a diagram showing a memory module 200 according to an example embodiment of the inventive concepts.

The memory module 200 may include one memory rank, and may include nine DRAM chips 242_0 through 242_8 having a data bus width of 8 bits. The memory module 200 may include the SPD chip 220. A DRAM chip 242_4 from among the DRAM chips 242_0 through 242_8 may be an ECC DRAM chip including an ECC. The ECC DRAM chip 242_4 may include parity data and CRC data.

Each of the DRAM chips 242_0 through 242_8 may transmit and receive data to and from a memory controller through an input/output pad including eight DQ contact points. The DQ contact points DQ0 through DQ7 may be grouped into two DQ groups to perform an error correction algorithm by 4 bits, with regard to data input and output through the eight DQ contact points DQ0 through DQ7. The DQ contact points DQ0 through DQ7 corresponding to each of the DRAM chips 242_0 through 242_8 may be grouped into a first DQ group including DQ contact points DQ0 through DQ3 and a second DQ group including DQ contact points DQ4 through DQ7. In one example embodiment, DQ contact points of the ECC DRAM chip 242_4 may be grouped into a parity DQ group in which parity data is input/output and a CRC DQ group in which CRC data is input/output. The SPD chip 220 may store DQ grouping information DQG_INFO indicating that the ×8 DRAM chips 242_0 through 242_8 are grouped into two DQ groups and may provide the DQ grouping information DQG_INFO to a memory controller in the error correction mode. As DQ contact points are grouped, the memory controller may recognize the DRAM chips 242_0 through 242_8 as a total of 18 DQ memory chips (e.g., DQ MC1 through DQ MC18) in the error correction mode. The memory controller may recognize that each of DQ memory chip DQ MC1 through DQ MC18 has a data bus width of 4 bits and may implement an error correction algorithm performed by 4 bits.

FIG. 7 is a diagram showing the DQ group manager 421 according to an example embodiment of the inventive concepts.

FIG. 7 is a diagram showing the DQ group manager 421 in a memory controller corresponding to the memory module of FIG. 6. The DQ group manager 421 may include DQ group management information for managing DQ groups. The DQ group management information may include DQ group address information DQG ADDR indicating address information about DQ groups, which are the results of DQ grouping. The DQ group address information DQG ADDR may represent address information about a memory corresponding to DQ contact points included in each of DQ groups in order to recognize respective memory chips as a plurality of DQ memory chips. For example, when DQ contact points of a DRAM chip_0 is grouped into two DQ groups, an address corresponding to a first DQ group may be stored as ADDR_0_DQG1, and an address corresponding to a second DQ group may be stored as ADDR_0_DQG2. Furthermore, for example, when DQ contact points of a DRAM chip_8 is grouped into two DQ groups, an address corresponding to a first DQ group may be stored as ADDR_8_DQG1, and an address corresponding to a second DQ group may be stored as ADDR_8_DQG2. The ECC engine 420 may recognize an ×8 DRAM chip as two ×4 DQ memory chips based on DQ group address information DQG ADDR and implement an error correction algorithm performed by 4 bits.

The DQ group management information stored in the DQ group manager 421 may include a mapping table 424. The mapping table 424 may be a table that matches information about data to fill a cache line of a memory controller in the error correction mode and addresses of DQ groups. For example, in the case of FIG. 6, because parity information is stored in a DRAM chip_4 242_4, an address ADDR_4_DQG1 of a first DQ group (a parity DQ group) of the DRAM chip_4 242_4 may be matched to an address of a DQ group to be recognized as a parity DRAM chip PD. Furthermore, because CRC information is stored in the DRAM chip_4 242_4, an address ADDR_4_DQG2 of a second DQ group of the DRAM chip_4 242_4 may be matched to an address of a DQ group (a CRC DQ group) to be recognized as a CRC DRAM chip CD. Because data is stored in the remaining DRAM chips, addresses may be sequentially matched. For example, an address ADDR_0_DQG1 of the address of a first DQ group of a DRAM chip_0 242_0 may be matched to an address of a DQ group to be recognized as first data device DD_1, and an address ADDR_8_DQG2 of a second DQ group of a DRAM chip_8 242_8 may be matched to a DQ group to be recognized as the last data device DD_16. A memory controller may fill a cache line by 4 bits in the error correction mode based on the mapping table 424.

FIG. 8 is a diagram showing a data structure in which an error correction algorithm is performed on the memory module of FIG. 6, according to an example embodiment of the inventive concepts. Compared with FIG. 3, because the data bus width of each memory chip is 8 bits, it is difficult to implement an error correction algorithm performed by 4 bits without DQ grouping. When DQ contact points of each memory chip may be grouped into two DQ groups, a memory controller may recognize each memory chip as two ×4 DQ memory chips. When the memory controller recognizes an ×8 memory chip as two ×4 DQ memory chips due to the DQ grouping, an ECC engine of the memory controller may implement an error correction algorithm performed by 4 bits. A method of correcting an error occurring at a data device DD_11 by performing an error correction may be the same or substantially similar identical to the method described above with reference to FIGS. 3 and 4.

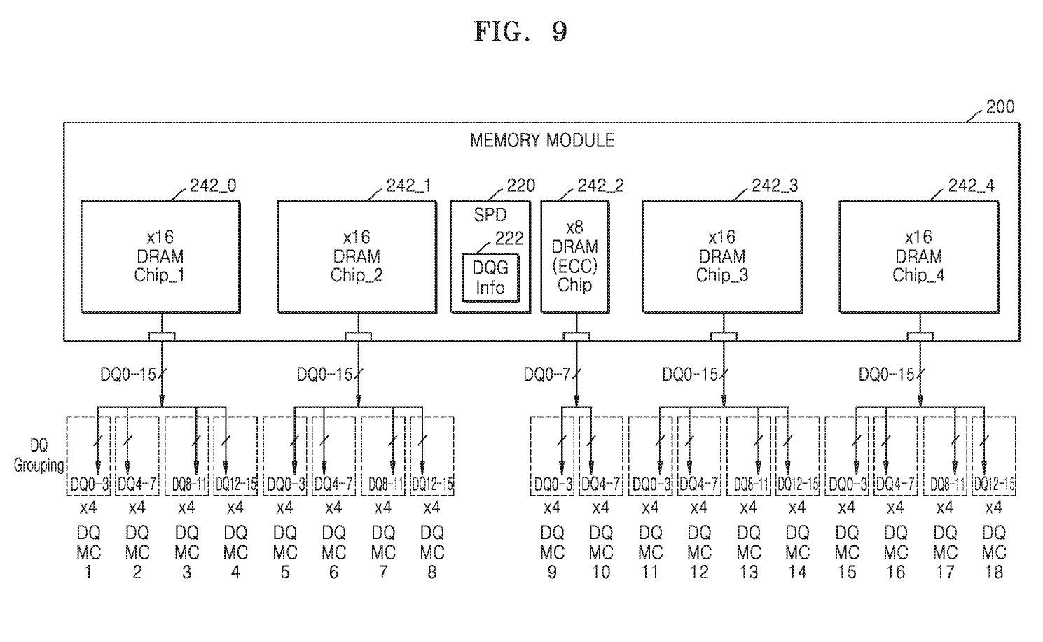

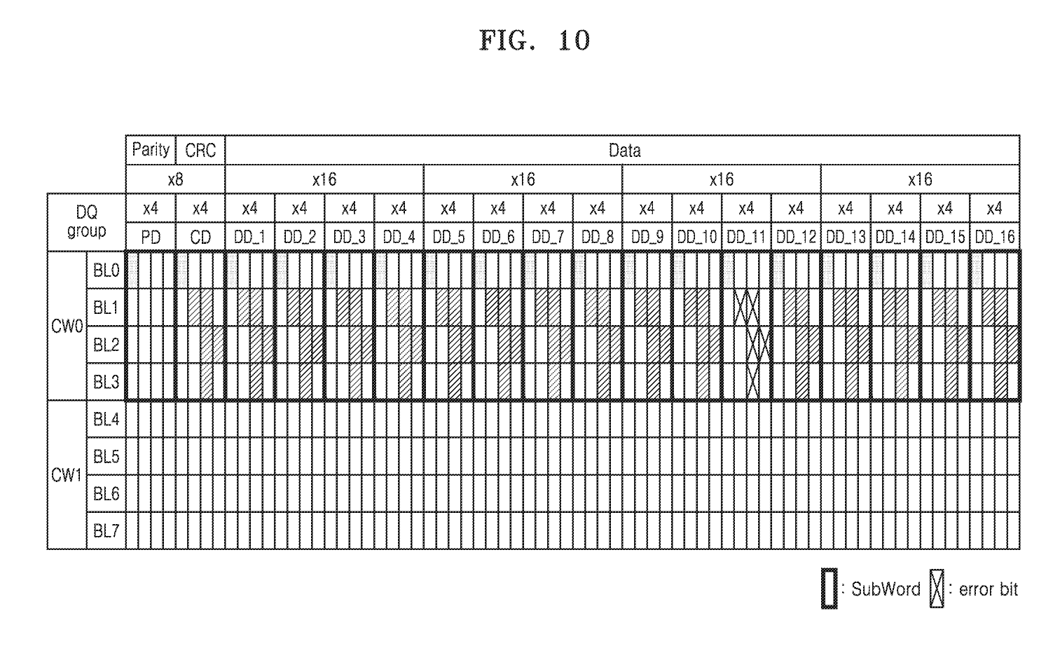

FIG. 9 is a diagram showing the memory module 200 according to an example embodiment of the inventive concepts.

The memory module 200 may include one memory rank, DRAM chips 242_0, 242_1, 242_3, and 242_4 having the data bus width of 16 bits, and a DRAM chip 242_2 having the data bus width of 8 bits. The memory module 200 may include the SPD chip 220. The ×8 DRAM chip 242_2 having the data bus width of 8-bit may be an ECC DRAM chip including an ECC. The ECC DRAM chip 242_2 may include parity data and CRC data.

Each of the DRAM chips 242_0 through 242_4 may transmit and receive data to and from a memory controller via input/output pads including 8 or 16 DQ contact points. To perform an error correction algorithm by, for example, 4 bits, 8 DQ contact points DQ0 through DQ7 may be grouped into two DQ groups, and 16 DQ contact points DQ0 through DQ15 may be grouped into four DQ groups. The DQ contact points DQ0 through DQ15 of the ×16 DRAM chips 242_0, 242_1, 242_2, and 242_3 may be grouped into a first DQ group including DQ contact points DQ0 through DQ3, a second DQ group including DQ contact points DQ4 through DQ7, a third DQ group including DQ contact points DQ8 through DQ11, and a fourth DQ group including DQ contact points DQ12 through DQ15. The ×8 DRAM chip 242_2 may be grouped into a first DQ group including DQ contact points DQ0 through DQ3 and a second DQ group including DQ contact points DQ4 through DQ7. In one example embodiment, the ECC DRAM chip 242_2 may be grouped into a parity DQ group in which parity data is input/output and a CRC DQ group in which CRC data is input/output. The SPD chip 220 may store information indicating that the ×16 DRAM chips 242_0, 242_1, 242_2, and 242_3 are grouped into four DQ groups and information indicating that the ×8 DRAM chip 242_2 is grouped into two DQ groups as DQ grouping information DQG_INFO, and may provide the DQ grouping information DQG_INFO to the memory controller in the error correction mode. As DQ contact points are grouped, the memory controller may recognize the DRAM chips 242_0 through 242_4 as a total of 18 DQ memory chips DQ MC1 through DQ MC18 in the error correction mode. The memory controller may recognize that each of the DQ memory chip DQ MC1 through DQ MC18 has a data bus width of 4 bits and may implement an error correction algorithm performed by 4 bits. Referring to FIG. 9, due to utilization of DQ grouping, in addition to being able to implement an error correction algorithm with a smaller correction data width, DRAM chips having different data bus widths may be embedded in one memory module. As illustrated, the data bus widths of the DRAM chips 242_0, 242_1, 242_3, and 242_4 for storing general data and the data bus width of the DRAM chip 242_2 for storing an ECC may be configured differently.

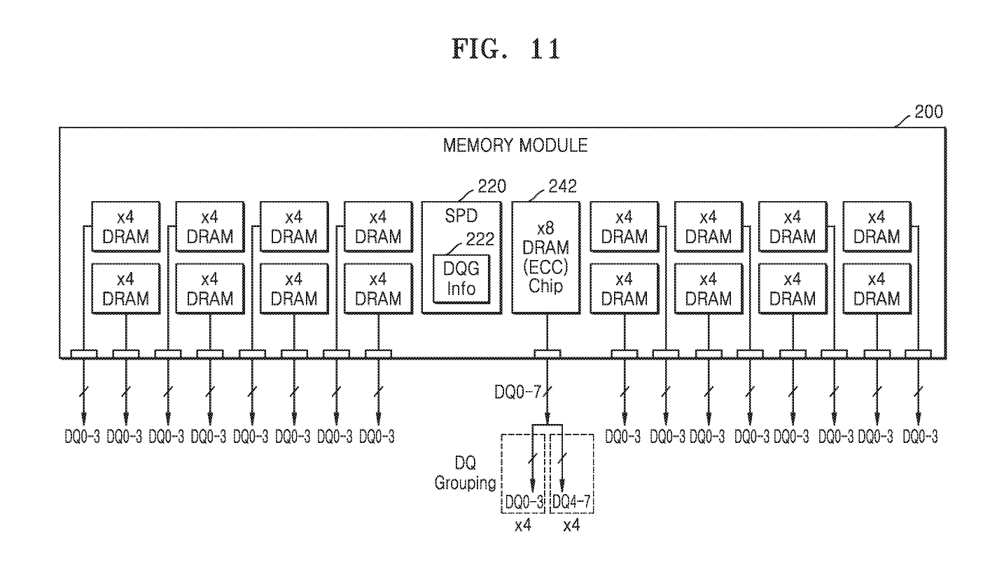

FIG. 10 is a diagram showing a data structure in which an error correction algorithm is performed on the memory module of FIG. 9 according to an example embodiment of the inventive concepts. Compared with FIG. 3, because the data bus width of an ECC memory chip is 8 bits and the data bus width of each of the remaining memory chips is 16 bits, it may be difficult to implement an error correction algorithm performed by 4 bits without DQ grouping. When DQ contact points of each memory chip are grouped into two or four DQ groups as shown in FIG. 9, a memory controller may recognize one memory chip as a plurality of ×4 DQ memory chips. When the memory controller recognizes an ×8 memory chip and an ×16 memory chip as ×4 DQ memory chips according to the DQ grouping, an ECC engine of the memory controller may implement an error correction algorithm performed by 4 bits. A method of correcting an error occurring at DD_11 by performing an error correction may be the same or substantially similar to the method described above with reference to FIGS. 3 and 4.

FIG. 11 is a diagram showing the memory module 200 according to an example embodiment of the inventive concepts.

The memory module 200 may include one memory rank, ×4 DRAM chips having the data bus width of 4 bits, and an ×8 DRAM chip 242 having the data bus width of 8 bits. The memory module 200 may include the SPD chip 220. The ×8 DRAM chip 242 having the data bus width of 8 bits may be an ECC DRAM chip including an ECC. The ECC DRAM chip may include parity data and CRC data.

Each of the ×4 DRAM chips may transmit and receive data to and from a memory controller through an input/output pad including four DQ contact points, and the ×8 DRAM chip may transmit and receive data to and from a memory controller through an input/output pad including eight DQ contact points. To perform an error correction algorithm by, for example, 4 bits, eight DQ contact points DQ0 through DQ7 may be grouped into two DQ groups. DQ contact points of the ×8 DRAM chip 242 may be grouped into a first DQ group including DQ contact points DQ0 through DQ3 and a second DQ group including connectors DQ4 through DQ7. The SPD chip 220 may store information indicating that the DQ contact points of the ×8 DRAM chip 242 is grouped into two DQ groups as DQ grouping information DQG_INFO and provide the DQ grouping information DQG_INFO to the memory controller in the error correction mode. As DQ contact points are grouped, the memory controller may recognize the ×8 DRAM chip 242 as two DQ memory chips in the error correction mode. The memory controller may recognize that every memory chip has the data bus width of 4 bits and may implement an error correction algorithm performed by 4 bits.

Referring to FIG. 11, due to utilization of DQ grouping, in addition to being able to implement an error correction algorithm with a smaller correction data width, DRAM chips having different data bus widths may be embedded in a single memory module. Thus, the ×8 DRAM chip 242 configured to store an ECC and having a greater data bus width than the ×4 DRAM chips for storing general data may be embedded in a single memory module.

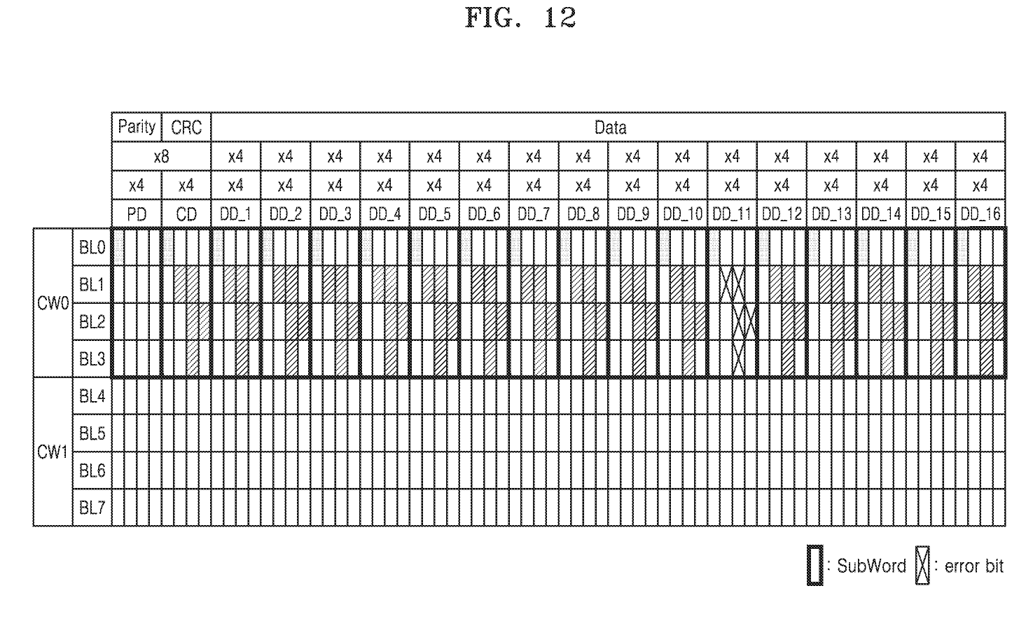

FIG. 12 is a diagram showing a data structure in which an error correction algorithm is performed on the memory module of FIG. 11 according to an example embodiment of the inventive concepts. Compared with FIG. 3, because the data bus width of an ECC memory chip is 8 bits and the data bus width of each of the remaining memory chips is 4 bits, it may be difficult to implement an error correction algorithm performed by, for example, 4 bits without DQ grouping. When DQ contact points of the ×8 DRAM chip 242 are grouped into two DQ groups as shown in FIG. 11, a memory controller may recognize the ×8 DRAM chip 242 as two ×4 DQ memory chips. When the memory controller recognizes an ×8 memory chip as two ×4 DQ memory chips according to the DQ grouping, an ECC engine of the memory controller may implement an error correction algorithm performed by, for example, 4 bits. A method of correcting an error occurring at DD_11 by performing an error correction may be the same or substantially similar identical to the method described above with reference to FIGS. 3 and 4.

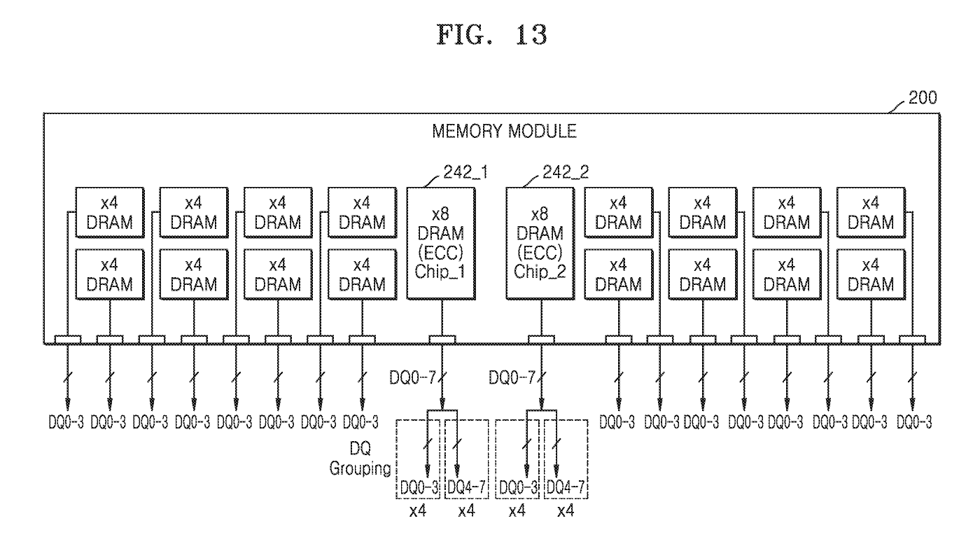

FIG. 13 is a diagram showing the memory module 200 according to an example embodiment of the inventive concepts.

The memory module 200 has the same configuration as the memory module shown in FIG. 11 except that the memory module 200 shown in FIG. 13 includes two ECC DRAM chips 242_1 and 242_2. Although not shown, the memory module 200 may include a SPD chip that provides DQ grouping information DQG_INFO to a memory controller in the error correction mode.

When memory chips comply with the standard of double data rate 5 (DDR5) or higher, the memory module 200 may need two parity data chips and two CRC data chips to perform an ECC operation. If the memory module 200 includes four ECC memory chips, the overall cost may increase.

Referring to FIG. 13, the memory module 200 may include the two ECC DRAM chips 242_1 and 242_2. A first ×8 DRAM chip 242_1 may be a first ECC DRAM chip and may include first parity data and first CRC data. DQ contact point DQ0 through DQ7 of the first ECC DRAM chip 242_1 may be grouped into two DQ groups. Each DQ group may include a first parity DQ group via which parity data is input and output and a first CRC DQ group via which CRC data is input and output. A second ×8 DRAM chip 242_2 may be a second ECC DRAM chip and may include second parity data and second CRC data. DQ contact point DQ0 through DQ7 of the second ECC DRAM chip 242_2 may be grouped into two DQ groups. Each DQ group may include a second parity DQ group via which parity data is input and output and a second CRC DQ group via which CRC data is input and output.

When DQ grouping is utilized, a same effect as that of four ECC DRAM chips may be obtained by using only two DRAM chips, and thus the overall cost may be reduced.

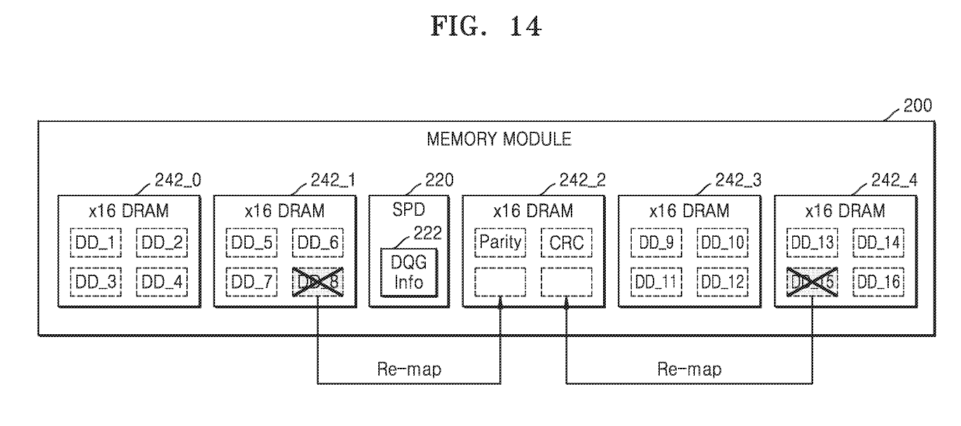

FIG. 14 is a diagram showing the memory module 200 according to an example embodiment of the inventive concepts.

The memory module 200 may include one memory rank and may include DRAM chips 242_0 through 242_4 having a data bus width of 16 bits. The memory module 200 may include the SPD chip 220. One DRAM chip 242_2 from among ×16 DRAM chips 242_0 through 242_4 may be an ECC DRAM chip including an ECC. The ECC DRAM chip 2422 may include parity data and CRC data.

Each of the ×16 DRAM chips 242_0 through 242_4 may transmit and receive data to and from a memory controller via an input/output pad including 16 DQ contact points. To perform an error correction algorithm by, for example, 4 bits, 16 DQ contact points DQ0 through DQ15 may be grouped into four DQ groups. The ×16 DRAM chips 242_0 through 242_4 may be grouped into a first DQ group including DQ contact points DQ0 through DQ3, a second DQ group including DQ contact points DQ4 through DQ7, a third DQ group including DQ contact points DQ8 through DQ11, and a fourth DQ group including DQ contact points DQ12 through DQ15. The SPD chip 220 may store information indicating that the ×16 DRAM chips 242_0 through 242_4 are grouped into four DQ groups and information related to the grouping as DQ grouping information DQG_INFO and provide the DQ grouping information DQG_INFO to the memory controller in the error correction mode. As the DQ contact points are grouped, the memory controller may recognize the ×16 DRAM chips 242_0 through 242_4 as four DQ memory chips in the error correction mode. The memory controller may recognize that every memory chips has the data bus width of 4 bits and may implement an error correction algorithm performed by 4 bits.

Referring to FIG. 14, a first DQ group of the ECC DRAM chip 242_2 may be a parity DQ group storing parity data, a second DQ group may be a CRC DQ group storing CRC data, and a third DQ group and a fourth DQ group may be empty DQ groups or spare DQ groups. A spare DQ group may replace a defective memory when a failure occurs in some of other DRAM chips.

For example, the fourth DQ group of a second ×16 DRAM chip 242_1 may be an eighth DQ device DD_8 recognized by a memory controller. When a failure occurs in the fourth DQ group of the second ×16 DRAM chip 242_1, a memory of a spare DQ group may replace a function performed by the memory of the fourth DQ group. To this end, the memory controller may store spare information about a spare DQ group in advance. The memory controller may re-allocate an address allocated to the fourth DQ group of the second ×16 DRAM chip 242_1 to a third DQ group of a third ×16 DRAM chip 242_2 based on the spare information. Furthermore, for example, a third DQ group of a fifth ×16 DRAM chip 242_4 may be a fifteenth DQ device DD_15 recognized by the memory controller. When a failure occurs in the third DQ group of the fifth ×16 DRAM chip 242_4, a function performed by a memory of the third DQ group may be performed by a memory of a spare DQ group instead. To this end, the memory controller may re-allocate an address allocated to the third DQ group of the fifth ×16 DRAM chip 242_4 to a fourth DQ group of the third ×16 DRAM chip 242_2 based on spare information. In other words, when DQ grouping is utilized, a spare DQ group may be assigned within one DRAM chip. Therefore, when a defect occurs in some DQ groups, defective DQ groups may be sequentially replaced with a spare DQ group. Therefore, the reliability, availability, and serviceability (RAS) features of an apparatus may be enhanced.

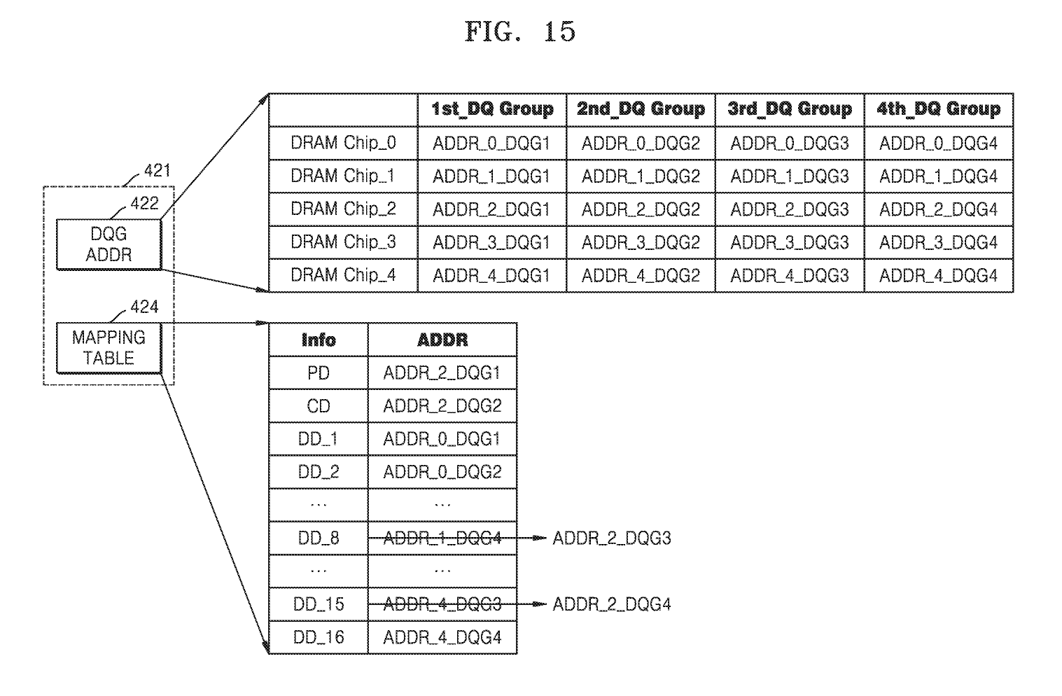

FIG. 15 is a diagram showing the DQ group manager 421 according to an example embodiment of the inventive concepts.

FIG. 15 may be a diagram showing the DQ group manager 421 in a memory controller corresponding to the memory module of FIG. 14. The DQ group manager 421 may store DQ group management information for managing DQ groups according to DQ grouping. The DQ group management information may include DQ group address information DQG ADDR indicating address information about DQ groups. The ECC engine 420 may recognize an ×16 DRAM chip as four ×4 DQ memory chips based on the DQG address information DQG ADDR and implement an error correction algorithm performed by 4 bits.

The DQ group management information stored by the DQ group manager 421 may include the mapping table 424. The mapping table 424 may be a table that matches information about data to fill a cache line of a memory controller in the error correction mode and addresses of DQ groups. For example, referring to FIG. 13, because parity information is stored in a third DRAM chip 242_2, an address ADDR_2_DQG1 of a first DQ group (a parity DQ group) of the third DRAM chip 242_2 may be matched to an address of a DQ group to be recognized as a parity DRAM chip PD. Furthermore, because CRC information is stored in a second DQ group of the third DRAM chip 242_2, an address ADDR_2_DQG2 of a second DQ group of the third DRAM chip 242_4 may be matched to an address of a DQ group (a CRC DQ group) to be recognized as a CRC DRAM chip CD. Because data is stored in the remaining DRAM chips, addresses may be sequentially matched. For example, an address ADDR_0_DQG1 of the address of a first DQ group of a first DRAM chip_0 242_0 may be matched to an address of a DQ group to be recognized as first data device DD_1, and an address ADDR_4_DQG4 of a fourth DQ group of the fourth DRAM chip 242_4 may be matched to a DQ group to be recognized as the last data device DD_16. A memory controller may fill a cache line by, for example, 4 bits in the error correction mode based on the mapping table 424.

Referring to FIGS. 14 and 15, when a defect occurs in a data device DD_8, an address matched to the data device DD_8 may be replaced with an address of a third DQ group, which is a spare DQ group existing in a third DRAM chip. Therefore, a memory controller may change the address matched to the data device DD_8 in the mapping table 424 from ADDR_1_DQG4 to ADDR_2_DQG3. For example, when a failure occurs in a data device DD_15, an address matched to the data device DD_15 may be replaced with an address of a fourth DQ group, which is a spare DQ group existing in the third DRAM chip. Therefore, the memory controller may change an address matched to the data device DD_15 in the mapping table 424 to ADDR_2_DQG4.

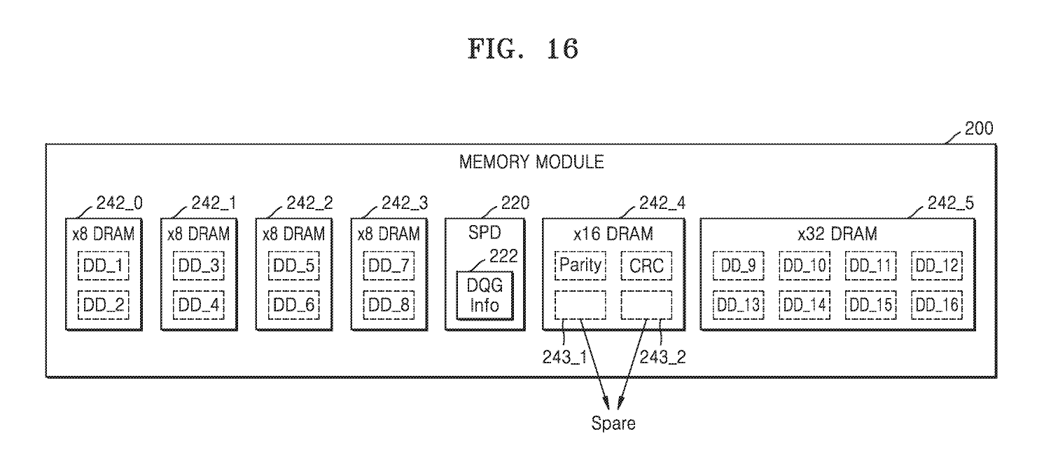

FIG. 16 is a diagram showing the memory module 200 according to an example embodiment of the inventive concepts.

The memory module 200 may include one memory rank and may include ×8 DRAM chips 242_0 through 242_3, an ×16 DRAM chip 242_4, and an ×32 DRAM chip 242_5. The memory module 200 may include the SPD chip 220. The ×16 DRAM chip 242_4 may be an ECC DRAM chip including an ECC. The ECC DRAM chip 242_4 may include parity data and CRC data.

Each of the ×8 DRAM chips 242_0 through 242_3 may transmit and receive data to and from a memory controller via an input/output pad including 8 DQ contact points, the ×16 DRAM chip 242_4 may transmit and receive data to and from the memory controller via an input/output pad including 16 DQ contact points and additional DQS contact point(s), and the ×32 DRAM chip 242_5 may transmit and receive data to and from the memory controller via an input/output pad including 32 DQ contact points and additional DQS contact point(s). To perform an error correction algorithm performed by, for example, 4 bits, eight DQ contact points DQ0 through DQ7 may be grouped into two DQ groups, sixteen DQ contact points DQ0 through DQ15 may be grouped into four DQ groups, and thirty-two DQ contact points DQ0 through DQ31 may be grouped into eight DQ groups. The SPD chip 220 may store information indicating that the ×8 DRAM chips 242_0 through 242_3 are grouped into two DQ groups, the ×16 DRAM chip 242_4 is grouped into four DQ groups, and the ×32 DRAM chip 242_5 is grouped into eight DQ groups as DQ grouping information DQG_INFO and provide the DQ grouping information DQG_INFO to the memory controller in the error correction mode. As DQ contact points are grouped, the memory controller may recognize that every memory chips has a data bus width of, for example, 4 bits and may implement an error correction algorithm performed by, for example, 4 bits.

Referring to FIG. 16, the ECC DRAM chip 242_4 and the DRAM chips 242_0 through 242_3 and 242_5 storing data included in the memory module 200 may have different data bus widths. Furthermore, the DRAM chips 242_0 through 242_3 and 242_5 storing data may have different data bus widths from one another. When DQ grouping is utilized as described above, the memory module 200 may be configured with memory chips having different data bus widths. Furthermore, some DQ groups in the ×16 ECC DRAM chip 242_4 may be used as spare DQ groups 243_1 and 243_2, and thus when a defect occurs in some of the other DRAM chips, the defect may be replaced.

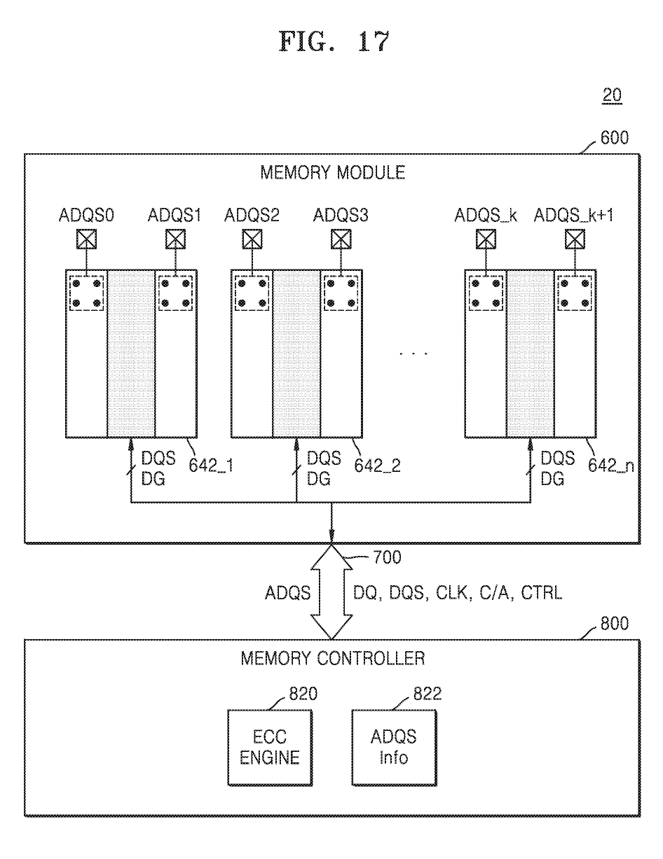

FIG. 17 is a diagram a memory system 20 according to an example embodiment of the inventive concepts.

The memory system 20 may include a memory module 600 and a memory controller 800. The memory module 600 and the memory controller 800 may transmit and receive various signals DQ, DQS, and CLK through a bus 700.

The memory module 600 may include a plurality of memory ranks or may include one memory rank. Although FIG. 17 shows that the memory module 600 includes one memory rank, the inventive concepts are not limited thereto. The memory module 600 may include a plurality of DRAM chips 642_1 through 642_n. The memory module 600 may include a SPD chip (not shown). The plurality of DRAM chips 642_1 through 642_n may be ×8 DRAM chips each having a data bus width of 8 bits. However, the inventive concepts are not limited thereto. For example, the plurality of DRAM chips 642_1 through 642_n may be DRAM chips each having a data bus width of, for example, 4 bits or 16 bits, or the plurality of DRAM chips 642_1 through 642_n may be DRAM chips having different data bus widths. For convenience of description, descriptions may be given below under an assumption that the plurality of DRAM chips 642_1 through 642_n are all ×8 DRAM chips each having a data bus width of 8 bits as shown in FIG. 17.

Because each of the DRAM chips 642_1 through 642n has a data bus width of 8 bits, it may be difficult for the memory controller 800 to implement an error correction algorithm performed by, for example, 4 bits. Therefore, the memory controller 800 may group DQ contact points of each of the plurality of DRAM chips 642_1 through 642_n into two DQ groups. Eight DQ contact points of a first DRAM chip 642_1 may be grouped into a first DQ group and a second DQ group. At this time, the first DRAM chip 642_1 may include additional DQS contact points ADQS0 and ADQS1 connected to each DQ group. The additional DQS contact points may be pins, and the term ‘pin’ may refer to a wide variety of electrical interconnections with respect to an integrated circuit or the like and may include, for example, pads or other electrical contact points on an integrated circuit. Similarly, DQ contact points of a second DRAM chip 642_2 may be grouped into two DQ groups, and the second DRAM chip 642_2 may include additional DQS contact points ADQS2 and ADQS3. The SPD chip (not shown) may store DQ grouping information DQG_INFO about the DRAM chips 642_1 through 642_n and may provide the DQ grouping information DQG_INFO to the memory controller 800 in the error correction mode.

The memory controller 800 may include an ECC engine 820 that performs error detection and error correction functions. The ECC engine 820 may store information about additional DQS contact points ADQS0, ADQS1, ADQS 2, and so on. In the error correction mode, the ECC engine 820 may recognize each of the plurality of DRAM chip 642_1 through 642_n as two DQ memory chips each having a data bus width of 4 bits based on additional DQS information ADQS Info. Therefore, the ECC engine 820 may implement an error correction algorithm performed by 4 bits with regard to the memory module 600. An error correction algorithm and operations of the memory module 600 and the memory controller 800 may be the same as or substantially similar to those described above with reference to FIG. 1.

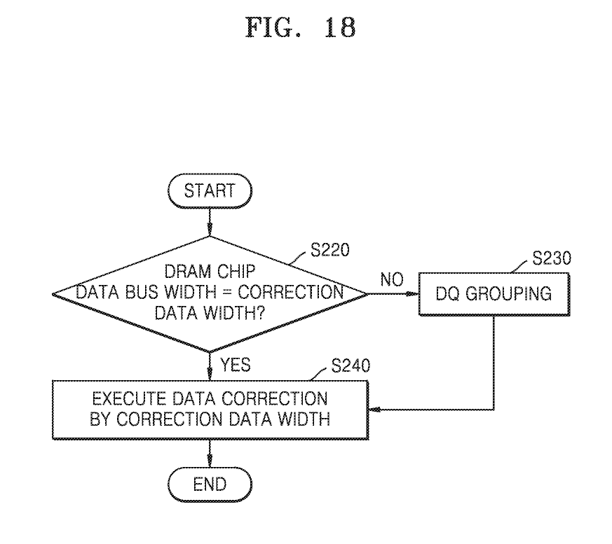

FIG. 18 is a flowchart showing that a memory controller performs an error correction function when DRAM chips of a memory module are DQ-grouped.

The memory controller may determine whether a data bus width of a DRAM chip is identical to a correction data width serving as a unit for performing an error correction algorithm (operation S220). When the data bus width of the DRAM chip is not identical to the correction data width, the memory controller may DQ-group the DRAM chip (operation S230). When the data bus width of the DRAM chip is identical to the correction data width, the memory controller may perform error correction without a separate DQ grouping operation (operation S240).

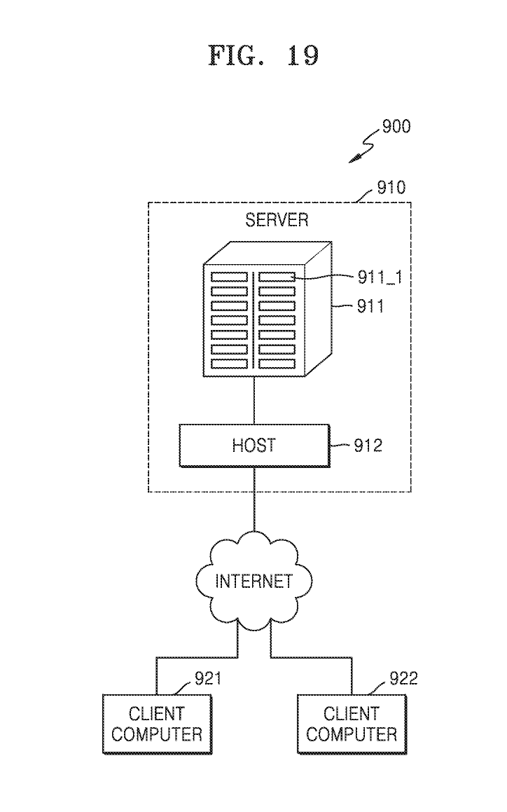

FIG. 19 is a block diagram showing a data processing system according to an example embodiment of the inventive concepts. A data processing system 900 may include a data server 910 and one or more client computers 921 and 922. The data server 910 and the one or more client computers 921 and 922 may be connected to one another via various networks, for example, the Internet or Wi-Fi. The data server 910 may correspond to a data center, an Internet data center, or a cloud data center.

The data server 910 may include a database 911 and a host 912. The database 911 may include a semiconductor memory device according to the above-described example embodiments. For example, the database 911 may include a plurality of DRAM modules 911_1 according to the above-described example embodiments. In other words, the semiconductor memory device and the memory controller in the above example embodiments may be used in a server system. The host 912 may store data in the database 911, read data from the database 911, and provide data to the client computers 921 and 922.

The host 912 may include a memory controller according to the above-described example embodiments. Therefore, the host 912 may generate parity information used for error detection and correction together with the data and additionally store the parity information in the database 911. According to an example embodiment, each of the plurality of memory modules 911_1 included in the database 911 may include a plurality of DRAM chips. When a data bus width of the plurality of DRAM chips is greater than a correction data width, the host 912 may DQ-group the plurality of DRAM chips and store information about DQ groups, e.g., address information about the DQ groups.

Data, parity data, and CRC data information may be read out and provided to the host 912 through a read operation with respect to the database 911. The host 912 may recover data of a DRAM chip in which the error occurred by using received information.

While the inventive concepts have been particularly shown and described with reference to some example embodiments thereof, it will be understood that various changes in form and details may be made therein without departing from the spirit and scope of the following claims.

What is claimed is:

1. A memory module comprising:
a plurality of memory chips each including DQ contact points which are grouped into at least one DQ group corresponding to a correction data width;
a serial presence detect (SPD) chip configured to store DQ grouping information about the plurality of memory chips; and
additional DQS contact points connected to the at least one DQ group, the additional DQS contact points configured to transmit signals to perform a data correction algorithm based on the correction data width in an error correction mode.

2. The memory module of claim 1, wherein
the plurality of memory chips includes a first memory chip having a first data bus width, the first data bus width being a natural number that is N times the correction data width (N is a natural number equal to or greater than 2), and
DQ contact points of the first memory chip are grouped into N DQ groups based on the DQ grouping information.

3. The memory module of claim 2, wherein
the first memory chip includes an ECC memory chip, the ECC memory chip configured to store parity data and cyclical redundancy code (CRC) data, and
DQ contact points of the ECC memory chip are grouped into a parity DQ group and a CRC DQ group, the parity DQ group being a DQ group via which the parity data is input and output, the CRC DQ group being a DQ group via which the CRC data is input and output.

4. The memory module of claim 3, wherein
the plurality of memory chips is configured to comply with a double data rate 5 (DDR5) standard, and
the plurality of memory chips further includes a second ECC memory chip which is configured to store second parity data and second CRC data.

5. The memory module of claim 2, wherein
the plurality of memory chips further includes a second memory chip having a second data bus width, the second data bus width being a natural number that is M times the correction data width (M is natural number equal to or greater than 2), and
DQ contact points of the second memory chip are grouped into M DQ groups.

6. The memory module of claim 2, wherein
the N DQ groups comprise a spare DQ group, and
the spare DQ group is managed based on spare information about the DQ group.

7. The memory module of claim 6, wherein
the plurality of memory chips includes a second memory chip having a second data bus width, the second data bus width being a natural number that is M times the correction data width (M is natural number equal to or greater than 2),
DQ contact points of the second memory chip are grouped into a first DQ group and a second DQ group, and
in response to the second DQ group being defective, the second DQ group is replaced with the spare DQ group based on the spare information.

8. The memory module of claim 1, wherein
the plurality of memory chips include a first memory chip having a first data bus width, and a second memory chip having a second data bus width, and
the first and second data bus widths are natural number multiples of the correction data width.

9. A method of correcting an error of a memory module, the method comprising:
grouping DQ contact points of memory chips of the memory module into DQ groups corresponding to a correction data width;
performing data correction with respect to the memory module by the correction data width.

10. The method of claim 9, further comprising:
determining whether the memory module is DQ-group based on DQ group information stored in a serial presence detect (SPD) chip of the memory module.

11. The method of claim 9, wherein the grouping comprises recognizing each of the memory chips as at least one DQ group memory chip having a data bus width identical to the correction data width based on DQ group manage information for managing the DQ groups.

12. The method of claim 9, wherein
the memory chips comprise an error correction code (ECC) memory chip configured to store parity data and cyclical redundancy code (CRC) data, and
the performing includes,
searching for an error code word in which an error occurred based on the CRC data,
locating an error bit within the error code word,
determining a memory chip including the error bit from the memory chips, and
correcting data.

13. The method of claim 12, wherein
the locating an error bit includes searching for a location of the error bit with respect to the error code word based on the parity data;
the determining including the error bit includes searching for the memory chip including the error bit by performing a CRC check that includes attempting data correction at the location of the error bit for each sub-word until the memory chip including the error bit is found, each sub-word having a data bus width identical to the correction data width; and
the correcting includes correcting the data at the location of the error bit of the determined memory chip.

14. The method of claim 9, wherein
the plurality of memory chips includes a first memory chip having a first data bus width, the first data bus width being a natural number that is N times the correction data width (N is a natural number equal to or greater than 2), and
the grouping comprises grouping DQ contact points of the first memory chip into N DQ groups.

15. The method of claim 14, wherein
the plurality of memory chips further includes a second memory chip having a second data bus width, the second data bus width being a natural number that is M times the correction data width (M is a natural number equal to or greater than 2), and
the grouping comprises grouping DQ contact points of the second memory chip into M DQ groups

16. A memory system comprising:
a plurality of memory chips; and
a memory controller configured to store DQ group management information about the plurality of memory chips, the memory controller including,
an error correction code (ECC) engine connected to DQ contact points of each of the plurality of memory chips, the ECC engine configured to perform a data correction algorithm with respect to data transmitted to the DQ contact points, and
a DQ group manager configured to group the DQ contact points into DQ groups corresponding to a correction data width and store the DQ group management information for managing the DQ groups.

17. The memory system of claim 16, wherein
the memory controller is further configured to recognize each of the plurality of memory chips as at least one DQ group memory device, a data bus width of the at least one DQ group memory device being identical to the correction data width based on the DQ group management information in an error correction mode, and
the ECC engine is further configured to perform the data correction algorithm with respect to data of the DQ contact points based on the DQ groups.

18. The memory system of claim 2, wherein
the correction data width is 4 bits, and
the data correction algorithm comprises a ×4 single device data correction (SDDC) technique.

19. The memory system of claim 1, wherein the DQ group management information comprises:
DQ group address information including address information corresponding to the DQ groups, respectively; and
a mapping table in which error correction data information is matched to the DQ group address information.

20. The memory system of claim 1, wherein the ECC engine is configured to perform error detection and error correction in an error correction mode.
